(19) United States
(12) Patent Application Publication
(10) Pub. No.: US 2025/0107200 A1
(43) Pub. Date: Mar. 27, 2025

(54) MULTI-LAYER DIELECTRIC GATE SPACER FOR FIN FIELD EFFECT TRANSISTORS (FINFET) AND GATE-ALL-AROUND (GAA) DEVICES

(71) Applicant: QUALCOMM Incorporated, San Diego, CA (US)

(72) Inventors: Xia LI, San Diego, CA (US); Junjing BAO, San Diego, CA (US); Biswa Ranjan PANDA, Bangaluru, Karnataka (IN)

(21) Appl. No.: 18/473,803

(22) Filed: Sep. 25, 2023

(51) Int. Cl. H01L 29/66; H01L 29/06; H01L 29/423; H01L 29/49; H01L 29/775; H01L 29/78

(52) U.S. Cl. CPC H10D 64/021; H10D 30/014; H10D 30/024; H10D 30/43; H10D 30/62; H10D 30/6735; H10D 62/121; H10D 64/679

(57) ABSTRACT

An electronic device having one or more non-planar transistors is disclosed. At least one of the non-planar transistors comprises: one or more gate structures; and one or more gate spacers associated with each of the one or more gate structures, at least one gate spacer of the one or more gate spacers having a multi-layer dielectric structure comprising an interior wall disposed next to a respective gate structure of the one or more gate structures, wherein the interior wall is formed from a first dielectric material, an exterior wall spaced apart from the interior wall, wherein the exterior wall is formed from a second dielectric material, and a third dielectric material disposed between the interior wall and the exterior wall, wherein a dielectric constant of the third dielectric material is lower than both the dielectric constants of the first and second dielectric materials.

### FIELD OF DISCLOSURE

The present disclosure generally relates to non-planar transistors, and more particularly, to multi-layer dielectric gate spacers for non-planar transistors, and methods of making the multi-layer dielectric gate spacers.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

Transistors are considered the fundamental building blocks of electronic devices and are frequently incorporated on IC chips. Such transistors have undergone several evolutionary changes to meet the ever-increasing demand for high performance, low power consumption, and miniaturization. As the dimensions of these transistors are scaled down to meet the demands for higher transistor densities, challenges such as short-channel effects, leakage currents, and power dissipation became increasingly problematic.

Non-planar transistors, such as Fin Field-Effect Transistors (FinFETs) and Gate-All-Around (GAA) transistors, have been developed to address these challenges. In FinFETs, the conducting channel is raised above the substrate, forming a fin-like structure. In GAA transistors, the gate material completely encircles the conducting channel-often formed from nanowires or nanosheets-resulting in improved electrostatic control and uniformity of the electric field. The non-planar transistor designs offer advantages such as lower leakage currents, improved threshold voltage control, and the ability to operate at reduced supply voltages, thus enhancing overall energy efficiency.

While such non-planar transistor architectures have improved transistor performance, they also present new challenges and complexities in terms of fabrication, material selection, and electrical characteristics. Accordingly, there is a need for improved non-planar transistor architectures and methods for making them.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device having one or more non-planar transistors includes one or more gate structures; and one or more gate spacers respectively associated with each of the one or more gate structures, at least one gate spacer of the one or more gate spacers having a multi-layer dielectric structure comprising an interior wall disposed next to a respective gate structure of the one or more gate structures, wherein the interior wall is formed from a first dielectric material, an exterior wall spaced apart from the interior wall, wherein the exterior wall is formed from a second dielectric material, and a third dielectric material disposed between the interior wall and the exterior wall, wherein a dielectric constant of the third dielectric material is lower than a dielectric constant of the first dielectric material and lower than a dielectric constant of the second dielectric material.

In an aspect, a non-planar transistor comprising: one or more gate structures; and one or more gate spacers respectively associated with each of the one or more gate structures, at least one gate spacer of the one or more gate spacers having a multi-layer dielectric structure comprising an interior wall disposed next to a respective gate structure of the one or more gate structures, wherein the interior wall is formed from a first dielectric material, an exterior wall spaced apart from the interior wall, wherein the exterior wall is formed from a second dielectric material, and a third dielectric material disposed between the interior wall and the exterior wall, wherein a dielectric constant of the third dielectric material is lower than a dielectric constant of the first dielectric material and lower than a dielectric constant of the second dielectric material.

In an aspect, a method of forming a fin field effect transistor (FinFET) includes forming a channel structure having a semiconductor channel between a source and a drain of the FinFET; forming a gate structure overlying the semiconductor channel; and forming at least one gate spacer associated with the gate structure, wherein the forming the at least one gate spacer comprises forming an interior wall next to the gate structure, wherein the interior wall is formed from a first dielectric material, forming an exterior wall spaced apart from the interior wall, wherein the exterior wall is formed from a second dielectric material, and forming a third dielectric material disposed between the interior wall and the exterior wall, wherein a dielectric constant of the third dielectric material is lower than a dielectric constant of the first dielectric material and lower than a dielectric constant of the second dielectric material.

In an aspect, a method of forming a gate-all-around (GAA) transistor includes forming a plurality of channel structures between a source and a drain of the GAA transistor; forming a gate structure associated with the plurality of channel structures; and forming at least one gate spacer associated with the gate structure, wherein the forming the at least one gate spacer comprises forming an interior wall next to the gate structure, wherein the interior wall is formed from a first dielectric material, forming an exterior wall spaced apart from the interior wall, wherein the exterior wall is formed from a second dielectric material, and forming a third dielectric material disposed between the interior wall and the exterior wall, wherein a dielectric constant of the third dielectric material is lower than a dielectric constant of the first dielectric material and lower than a dielectric constant of the second dielectric material.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1A and FIG. 1B illustrate the various elements of a Fin Field-Effect Transistor (FinFET), according to aspects of the disclosure.

FIG. 2A and FIG. 2B illustrate the various elements of a FinFET employing an example multi-layer dielectric gate spacer, according to aspects of the disclosure.

FIG. 3A and FIG. 3B illustrate the various elements of a FinFET employing an example multi-layer dielectric gate spacer, according to aspects of the disclosure.

FIG. 4A and FIG. 4B illustrate the various elements of a Gate-All-Around (GAA) transistor, according to aspects of the disclosure.

FIG. 5A and FIG. 5B illustrate various elements of a GAA transistor that includes multi-layer dielectric structures for the inner and outer gate spacers, according to aspects of the disclosure.

FIG. 6A and FIG. 6B illustrate various elements of a GAA transistor that includes multi-layer dielectric structures for the inner and outer gate spacers, according to aspects of the disclosure.

FIG. 7A through FIG. 7I show an example process that may be used to fabricate a FinFET, according to aspects of the disclosure.

FIG. 8A through FIG. 8R show an example process that may be used to fabricate a GAA transistor, according to aspects of the disclosure.

FIG. 9 is a flowchart showing an example method for fabricating a FinFET, according to aspects of the disclosure.

FIG. 10 is a flowchart showing an example method for fabricating a GAA transistor, according to aspects of the disclosure.

FIG. 11 illustrates a profile view of a package that includes a surface mount substrate, an integrated device, and an integrated passive device, according to aspects of the disclosure.

FIG. 12 illustrates an example method for providing or fabricating a package that includes an integrated device comprising an electronic component mounted in a core, according to aspects of the disclosure.

FIG. 13 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments.

In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. It will also be understood that when a layer is described as “over,” “overlying,” “under,” “underlying,” another layer does not necessarily preclude the use of intermediate layers and/or materials that may otherwise be used to ensure adhesion between the layers. Still further, it will be understood that when a layer is described as “over,” “overlying,” “under,” “underlying,” another layer that such terms are used with reference to the orientations of such layers as depicted in the reference frame shown in the corresponding figures.

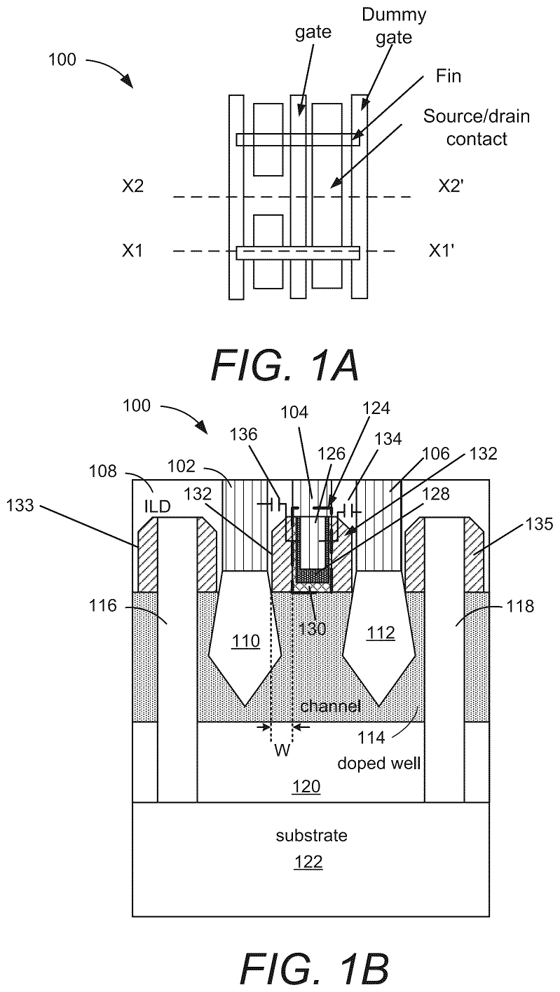

FIG. 1A and FIG. 1B illustrate the various elements of a Fin Field-Effect Transistor (FinFET) 100, according to aspects of the disclosure. Here, FIG. 1A is a top plan view of the FinFET 100 while FIG. 1B is a cross-sectional view of the FinFET 100 through axis X1-X1′. In this example, the FinFET 100 is configured to receive bias and control signals through metallization structures 102, 104, and 106. In an aspect, the metallization structures 102 and 106 may be formed from cobalt, manganese, or tungsten and metallization structure 104 may be formed from tungsten. Metallization structures 102 and 106 extend through an inter-layer dielectric 108 into contact with the epitaxial structures 110 and 112 that are disposed on opposite sides of a doped channel 114 and form the source/drain (S/D) structures of the FinFET 100. In an aspect, the epitaxial structures 110 and 112 may be formed from an epitaxial silicon-germanium (eSiGe) and/or epitaxial silicon (eSi) material. The doped channel 114 is bounded on its lateral sides by dummy gate structures 116 and 118 and underneath by a doped well 120 that overlies a substrate 122. The doping (e.g., n or p doping) of the doped well 120 depends on the doping used for the doped channel 114.

FinFET 100 includes a gate structure 124 that overlies the doped channel 114. In an aspect, the gate structure 124 includes a gate contact 126 that is bounded at its exterior by a layer 128 of a work function metal. In turn, the layer 128 of the work function metal is bounded at its exterior by a layer 130 of gate dielectric, which is typically formed from a high dielectric constant material.

In the example shown in FIG. 1B, the gate structure 124 is associated with a corresponding gate spacer 132. In an aspect, the gate spacer 132 provides mechanical support to the gate structure 124, thereby enhancing its mechanical stability and providing electrical isolation of the gate structure 124 from other elements of the FinFET 100. The gate spacer 132 is typically formed from a single layer of a high dielectric constant material. In this example, as well as in other examples described herein, the gate spacer may have a wall width W of about 5 nanometers. In an aspect, dummy gate spacers 133 and 135 may have the same structure, may be formed from the same material, and/may be produced concurrently with other gate elements to simplify fabrication of the FinFET 100. In an aspect, the dummy gate is filled with a dielectric material to function as an isolation channel.

Certain aspects of the disclosure are implemented with a recognition that the use of a single layer of high dielectric constant material as the gate spacer may increase parasitic capacitances that degrade transistor performance by increasing power consumption and reducing the switching speed of the transistor. Here, a parasitic capacitance 134 (shown in schematic form as a capacitor) is formed between the metallization structure 106 and the gate contact 126. Similarly, a parasitic capacitance 136 is formed between the metallization structure 102 and the gate contact 126. The values of the parasitic capacitances 134 and 136 can be quite large in the conventional FinFET structure shown in FIG. 1B.

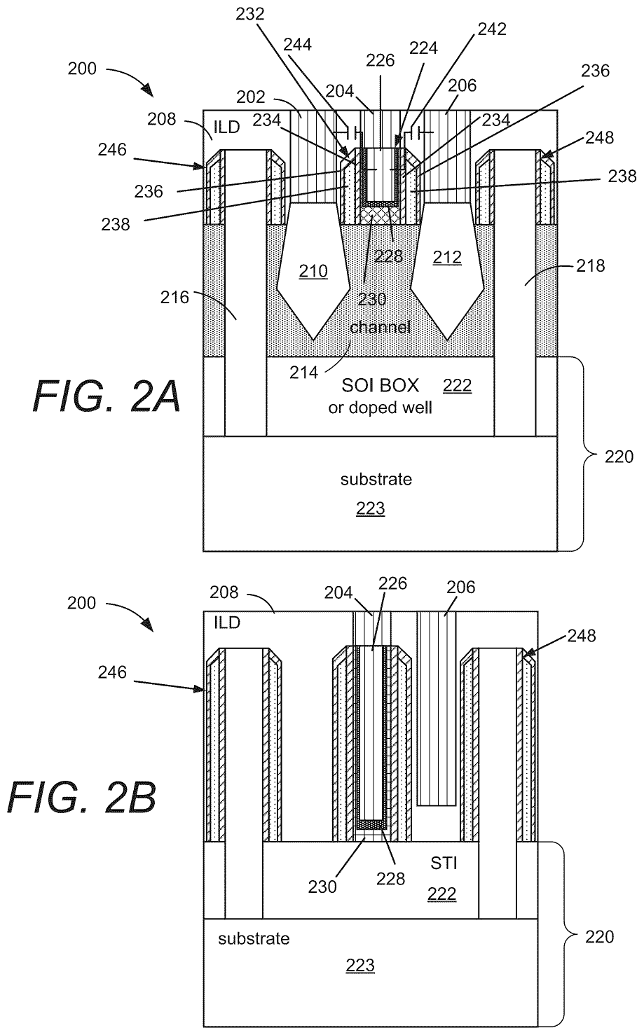

Certain aspects of the disclosure are implemented with a recognition that the structure and materials used for the gate spacer 132 can reduce the values of the parasitic capacitances 134 and 136, thereby enhancing the performance of the FinFET. FIG. 2A and FIG. 2B illustrate the various elements of a FinFET 200 employing an example multi-layer dielectric gate spacer, according to aspects of the disclosure. Here, FIG. 2A is a cross-sectional view of FinFET 200 through the cross-section X1-X1′ shown in FIG. 1A while FIG. 2B is a cross-sectional view through the cross-section X2-X2′ shown in FIG. 1A.

In this example, the FinFET 200 is configured to receive bias and control signals through metallization structures 202, 204, and 206. In an aspect, the metallization structures 202 and 206 may be formed from cobalt, manganese, or tungsten, and metallization structure 204 may be formed from tungsten. Metallization structures 202 and 206 extend through an inter-layer dielectric 208 into contact with the epitaxial structures 210 and 212 that are disposed on opposite sides of a doped channel 214 and form the S/D structures of the FinFET 200. In an aspect, the epitaxial structures 210 and 212 may be formed from an eSiGe and/or eSi material. The doped channel 214 is bounded on its lateral sides by dummy gate structures 216 and 218 and underneath by a base structure 220 comprised of a layer 222 that overlies a substrate 223. In an aspect, the layer 222 may be a doped well having a doping (e.g., n or p doping) that depends on the doping used for the doped channel 214. Additionally, or in the alternative, the layer 222 may comprise a silicon-on-insulator (SIO) and/or buried oxide (BOX) layer.

FinFET 200 includes a gate structure 224 that overlies the doped channel 214. In an aspect, the gate structure 224 includes a gate contact 226 that is bounded at its exterior by a layer 228 of a work function metal. In turn, the layer 228 of the work function metal is bounded at its exterior by a gate dielectric layer 230, which is typically formed from a high dielectric constant material.

In this example, the gate structure 224 is associated with a corresponding gate spacer 232. Unlike conventional gate spacers, gate spacer 232 is formed as a multi-layer dielectric structure. In an aspect, the gate spacer 232 includes an interior wall 234 disposed next to the gate structure 224 (shown in this example as immediately adjacent to the gate dielectric layer 230). In an aspect, the interior wall 234 is formed from a high dielectric constant material. The gate spacer 232 also includes an exterior wall 236 that is laterally spaced from the interior wall 234 and also formed from a high dielectric constant material, which may be the same or a different dielectric material than used for the interior wall 234. Still further, the gate spacer 232 includes a low dielectric constant material 238 disposed between the interior wall 234 and the exterior wall 236. In an aspect, the interior wall 234 and exterior wall 236 may be formed from a high dielectric constant material such as silicon nitride (SiN). The low dielectric constant material 238 may be a low dielectric constant material such as silicon dioxide (SiO2), silicon oxynitride (SiON), silicon carbide (SiC), an air gap, or any combination thereof. In an aspect, the low dielectric constant material 238 is formed as a single layer that extends from an interior surface of the interior wall 234 and an interior surface of the exterior wall 236. The FinFET 200 may also include dummy gate spacers 246 and 248 that have a similar multi-layer dielectric structure as the gate spacer 232.

The overall dielectric constant of the gate spacer 232 is lower than the dielectric constant of conventional gate spacers typically used in FinFETs (e.g., gate spacer 132 shown in FIG. 1A). As such, the parasitic capacitances 242 and 244 are significantly less than the parasitic capacitances (e.g., parasitic capacitances 136 and 134 shown in FIG. 1B) associated with conventional gate spacers. Consequently, the performance of the FinFET 200 is increased through decreased power consumption and increased switching speed.

FIG. 2B is a cross-sectional view of the example FinFET 200 through the cross-section X2-X2′ shown in FIG. 1A. In this region, the layer 222 of the base structure 220 may provide Shallow Trench Isolation (STI) that electrically isolates individual transistors, such as FinFET 200, from other active components within an IC. In an aspect, the STI process may involve etching shallow trenches into the substrate 223, which are then filled with an insulating material, such as silicon dioxide (SiO2).

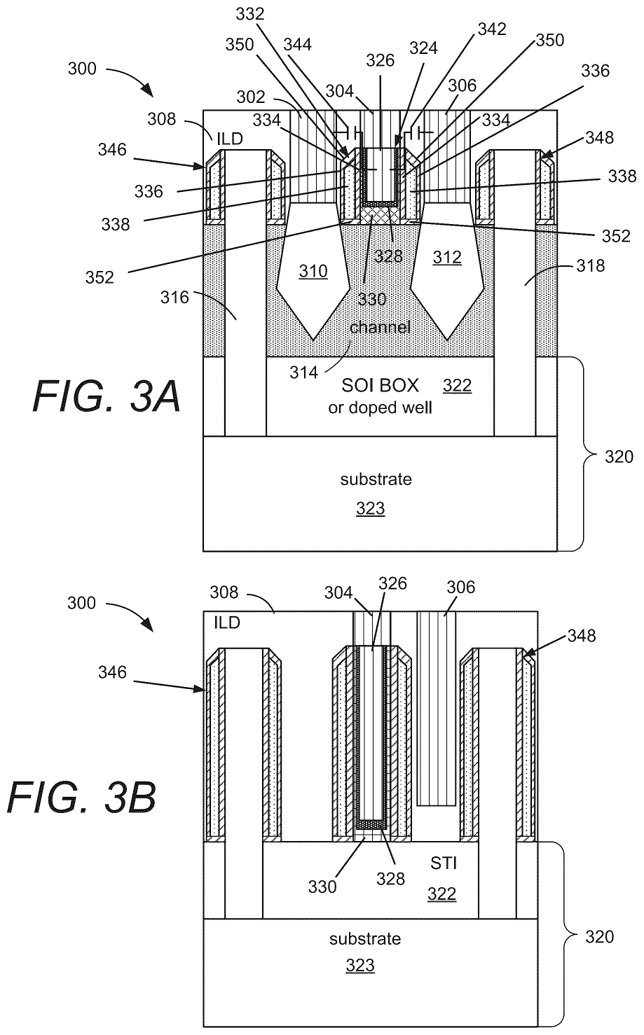

FIG. 3A and FIG. 3B illustrate the various elements of a FinFET 300 employing an example multi-layer dielectric gate spacer, according to aspects of the disclosure. Here, FIG. 3A is a cross-sectional view of FinFET 300 through the cross-section X1-X1′ shown in FIG. 1A while FIG. 3B is a cross-sectional view through the cross-section X2-X2′ shown in FIG. 1A.

In this example, the FinFET 300 is configured to receive bias and control signals through metallization structures 302, 304, and 306. In an aspect, the metallization structures 302 and 306 may be formed from cobalt, manganese, or tungsten and metallization structure 304 may be formed from tungsten. Metallization structures 302 and 306 extend through an inter-layer dielectric 308 into contact with the epitaxial structures 310 and 312 that are disposed on opposite sides of a doped channel 214 and form the S/D structures of the FinFET 300. In an aspect, the epitaxial structures 310 and 312 may be formed from an eSiGe and/or eSi material. The doped channel 314 is bounded on its lateral sides by dummy gate structures 316 and 318 and underneath by a base structure 320 comprised of a layer 322 that overlies a substrate 323. In an aspect, the layer 322 may be a doped well having a doping (e.g., n or p doping) that depends on the doping used for the doped channel 314. Additionally, or in the alternative, the layer 322 may comprise an SiO2 and/or a BOX layer.

FinFET 300 includes a gate structure 324 that overlies the doped channel 314. In an aspect, the gate structure 324 includes a gate contact 326 that is bounded at its exterior by a layer 328 of a work function metal. In turn, the layer 328 of the work function metal is bounded at its exterior by a gate dielectric layer 330, which is typically formed from a high dielectric constant material.

In this example, the gate structure 324 is associated with a corresponding gate spacer 332. In an aspect, the gate spacer 332 includes an interior wall 334 disposed next to the corresponding gate structure 324 (shown in this example as immediately adjacent to the gate dielectric layer 330). In an aspect, the interior wall 334 is formed from a high dielectric constant material. The gate spacer 332 also includes an exterior wall 336 that is laterally spaced from the interior wall 334 and also formed from a high dielectric constant material, which may be the same or a different dielectric material than used for the interior wall 334. Still further, the gate spacer 332 includes a low dielectric constant material 338 disposed between the interior wall 334 and the exterior wall 336. In accordance with certain aspects of the disclosure, the gate spacer 332 also includes an upper wall 350 of a high dielectric constant material that overlies the low dielectric constant material 338 that extends between the interior wall 334 and the exterior wall 336. Additionally, the gate spacer 332 includes a lower wall 352 of a high dielectric constant material below the low dielectric constant material 338 that extends between the interior wall 334 and the exterior wall 336. In an aspect, the interior wall 334, the exterior wall 336, the upper wall 350, and the lower wall 352 may be formed from the same or different dielectric materials. In an aspect, the walls 334, 336, 350, and 352 may be formed from a high dielectric constant material such as silicon nitride (SiN). The low dielectric constant material 338 may be a low dielectric constant material such as silicon dioxide (SiO2), an air gap, or any combination thereof. In an aspect, the low dielectric constant material 338 is formed as a single layer that extends from an interior surface of the interior wall 334 and an interior surface of the exterior wall 336. The FinFET 300 may also include, dummy gate spacers 346 and 348 that have a similar multi-layer dielectric structure as the gate spacer 332 to simplify fabrication of the FinFET 300.

The overall dielectric constant of the gate spacer 332 is lower than the dielectric constant of conventional gate spacers typically used in FinFETs (e.g., gate spacer 132 shown in FIG. 1A). As such, the parasitic capacitances 342 and 344 are significantly less and the parasitic capacitances associated with conventional gate spacers (e.g., parasitic capacitances 136 and 134 shown in FIG. 1B). Consequently, the performance of the FinFET 300 is increased through decreased power consumption and increased switching speed.

FIG. 3B is a cross-sectional view of the example FinFET 300 through the cross-section X2-X2′ shown in FIG. 1A. In this region, the layer 322 of the base structure 320 may provide STI that electrically isolates individual transistors, such as FinFET 300, from other active components within an IC. In an aspect, the STI process may involve etching shallow trenches into the substrate 323, which are then filled with an insulating material, such as silicon dioxide (SiO2).

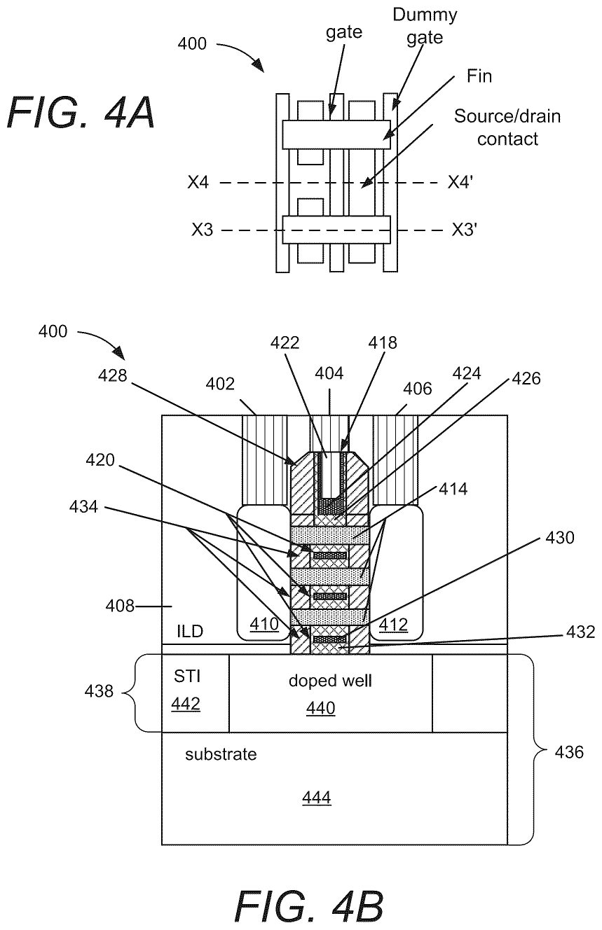

FIG. 4A and FIG. 4B illustrate the various elements of a Gate-All-Around (GAA) transistor 400, according to aspects of the disclosure. Here, FIG. 4A is a top plan view of the GAA transistor 400 while FIG. 4B is a cross-sectional view of the GAA transistor 400 through axis X3-X3′. In this example, the GAA transistor 400 is configured to receive bias and control signals through metallization structures 402, 404, and 406. In an aspect, the metallization structures 402 and 406 may be formed from cobalt, manganese, or tungsten and metallization structure 404 may be formed from tungsten. Metallization structures 402 and 406 extend through an inter-layer dielectric 408 into contact with epitaxial structures 410 and 412 that are disposed on opposite sides of multiple doped channels 414 and form the S/D structures of the GAA transistor 400. In an aspect, the doped channels 414 may be formed from nanosheets (e.g., in the configuration shown in FIG. 4B). However, it will be understood that similar doped channels for a GAA transistor may be formed from forksheets. In an aspect, the epitaxial structures 410 and 412 may be formed from an eSiGe and/or eSi material.

GAA transistor 400 includes at least one gate structure associated with each of the doped channels 414. In this example, the GAA transistor 400 includes an outer gate structure 418 and a plurality of inner gate structures 420. In an aspect, the outer gate structure 418 includes a gate contact 422 that is bounded at its exterior by a layer 424 of a work function metal. In turn, the layer 424 of the work function metal is bounded at its exterior by a layer 426 of gate dielectric, which is typically formed from a high dielectric constant material.

In the example shown in FIG. 4B, the outer gate structure 418 is associated with a corresponding outer gate spacer 428. The outer gate spacer 428 is typically formed from a single layer of a high dielectric constant material. In an aspect, dummy gate spacers (not shown) having the same structure and formed from the same material may be produced during fabrication of the GAA transistor 400.

In an aspect, each inner gate structure 420 includes an interior layer of a work function metal 430 that is surrounded by a gate dielectric layer 432. Each inner gate structure 420 is associated with a corresponding inner gate spacer 434. The inner gate spacers 434 are typically formed from a single layer of a high dielectric constant material.

The foregoing elements of the GAA transistor 400 overlie a base structure 436. In this example, the base structure 436 includes a layer 438 that includes a doped well 440 and an STI structure 442. Layer 438 overlies a substrate layer 444.

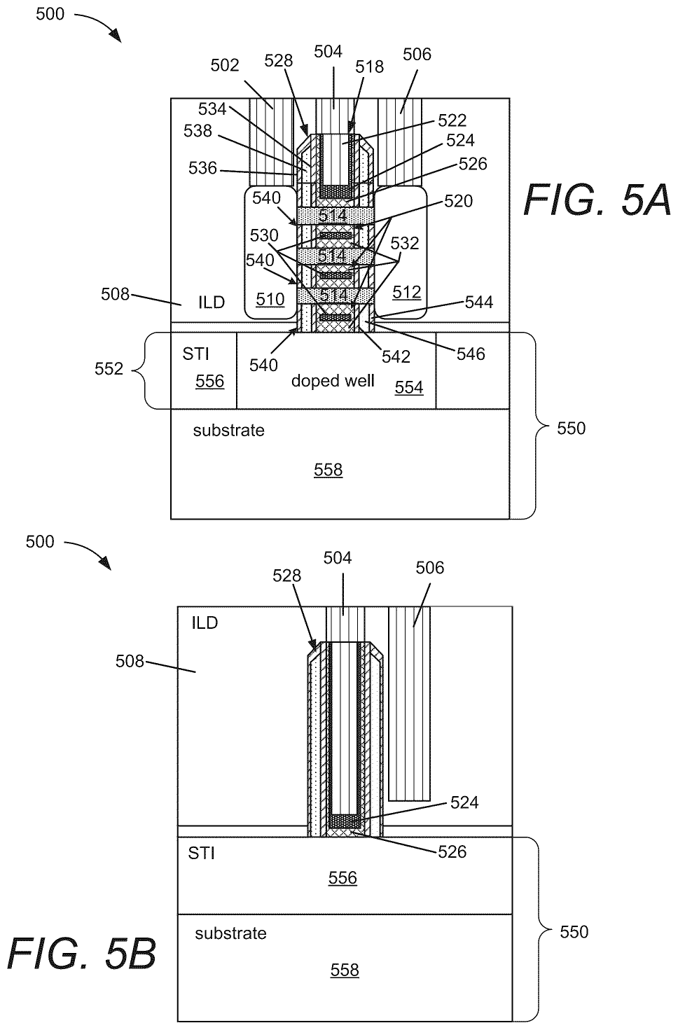

FIG. 5A and FIG. 5B illustrate various elements of a GAA transistor 500 that includes multi-layer dielectric structures for the inner and outer gate spacers, according to aspects of the disclosure. Here, FIG. 5A is a cross-sectional view of the GAA transistor 500 through the cross-section X3-X3′ shown in FIG. 4A while FIG. 5B is a cross-sectional view through the cross-section X4-X4′ shown in FIG. 4A.

In this example, the GAA transistor 500 is configured to receive bias and control signals through metallization structures 502, 504, and 506. In an aspect, the metallization structures 502 and 506 may be formed from cobalt, manganese, or tungsten and metallization structure 504 may be formed from tungsten. Metallization structures 502 and 506 extend through an inter-layer dielectric 508 into contact with the epitaxial structures 510 and 512 that are disposed on opposite sides of multiple doped channels 514 and form the S/D structures of the GAA transistor 500. In an aspect, the doped channels 514 may be formed from nanosheets (e.g., as in the configuration shown in FIG. 5B). However, it will be understood that similar doped channels for such GAA transistors may also be formed from forksheets. In an aspect, the epitaxial structures 510 and 512 may be formed from an eSiGe and/or eSi material.

GAA transistor 500 includes at least one gate structure associated with each of the doped channels 514. In this example, the GAA transistor 500 includes an outer gate structure 518 and a plurality of inner gate structures 520. In an aspect, the outer gate structure 518 includes a gate contact 522 that is bounded at its exterior by a layer 524 of a work function metal. In turn, the layer 524 of the work function metal is bounded at its exterior by a gate dielectric layer 526, which is typically formed from a high dielectric constant material.

In the example shown in FIG. 5A, the outer gate structure 518 is associated with a corresponding outer gate spacer 528. Unlike conventional outer gate spacers, outer gate spacer 528 is formed as a multi-layer dielectric structure. In an aspect, the outer gate spacer 528 includes an interior wall 534 disposed next to the outer gate structure 518 (shown in this example as immediately adjacent to the gate dielectric layer 526). In an aspect, the interior wall 534 is formed from a high dielectric constant material. The outer gate spacer 528 also includes an exterior wall 536 that is laterally spaced from the interior wall 534 and also formed from a high dielectric constant material, which may be the same or a different dielectric material than used for the interior wall 534. Still further, the outer gate spacer 528 includes a low dielectric constant material 538 disposed between the interior wall 534 and the exterior wall 536. In an aspect, the interior wall 534 and exterior wall 536 may be formed from a high dielectric constant material such as SiN. The low dielectric constant material 538 may be a low dielectric constant material such as SiO2, an air gap, or any combination thereof. In an aspect, the low dielectric constant material 538 is formed as a single layer that extends from an interior surface of the interior wall 534 and an interior surface of the exterior wall 536. The GAA transistor 500 may also include, dummy gate spacers (not shown) that have a similar multi-layer dielectric structure as the outer gate spacer 528.

In an aspect, each inner gate structure 520 includes an interior layer of a work function metal 530 that is surrounded by a gate dielectric layer 532. Each inner gate structure 520 is associated with a corresponding inner gate spacer 540. Unlike conventional inner gate spacers, inner gate spacers 540 are formed as multi-layer dielectric structures. In an aspect, each inner gate spacer 540 includes an interior wall 542 disposed next to the corresponding inner gate structure 520 (shown in this example as immediately adjacent to the gate dielectric layer 532). In an aspect, the interior wall 542 is formed from a high dielectric constant material. Each inner gate spacer 540 also includes an exterior wall 544 that is laterally spaced from the interior wall 542 and also formed from a high dielectric constant material, which may be the same or a different dielectric material than used for the interior wall 542. Still further, each inner gate spacer 540 includes a low dielectric constant material 546 disposed between the interior wall 542 and the exterior wall 544. In an aspect, the interior wall 542 and exterior wall 544 may be formed from a high dielectric constant material such as silicon nitride (SiN). The low dielectric constant material 546 may be a low dielectric constant material such as silicon dioxide (SiO2), an air gap, or any combination thereof. In an aspect, the low dielectric constant material 546 of each inner gate spacer 540 is formed as a single layer that extends from an interior surface of the interior wall 542 of the corresponding inner gate spacer 540 and an interior surface of the exterior wall 544 of the corresponding inner gate spacer 540.

The foregoing elements of the GAA transistor 500 overlie a base structure 550. In this example, the base structure 550 includes a layer 552 that includes a doped well 554 and an STI structure 556. Layer 552 overlies a substrate layer 558. It will be recognized that the base structure 550 will be different depending on the starting elements used in the fabrication process (e.g., bulk, SOI, etc.).

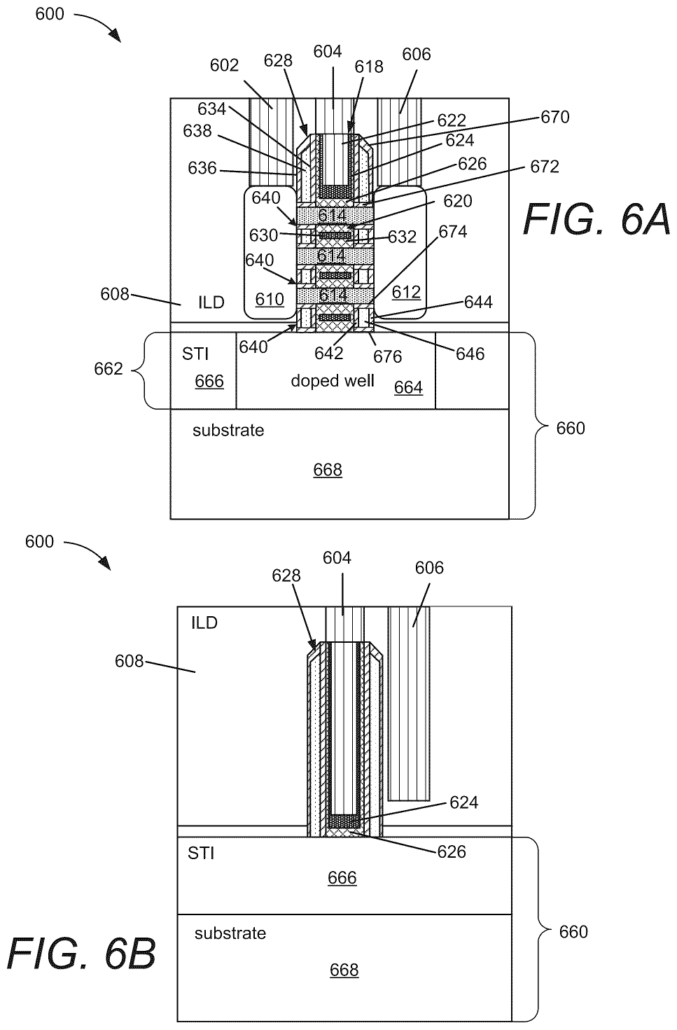

FIG. 6A and FIG. 6B illustrate various elements of a GAA transistor 600 that includes multi-layer dielectric structures for the inner and outer gate spacers, according to aspects of the disclosure. Here, FIG. 6A is a cross-sectional view of the GAA transistor 600 through the cross-section X3-X3′ shown in FIG. 4A while FIG. 6B is a cross-sectional view through the cross-section X4-X4′ shown in FIG. 4A.

In this example, the GAA transistor 600 is configured to receive bias and control signals through metallization structures 602, 604, and 606. In an aspect, the metallization structures 602 and 606 may be formed from cobalt, manganese, or tungsten and metallization structure 604 may be formed from tungsten. Metallization structures 602 and 606 extend through an inter-layer dielectric 608 into contact with the epitaxial structures 610 and 612 that are disposed on opposite sides of multiple doped channels 614 and form the S/D structures of the GAA transistor 600. In an aspect, the doped channels 614 may be formed from nanosheets (e.g., in the configuration shown in FIG. 6B). However, it will be understood that similar doped channels for such GAA transistors may also be formed from forksheets. In an aspect, the epitaxial structures 610 and 612 may be formed from an eSiGe and/or eSi material.

GAA transistor 600 includes at least one gate structure associated with each of the doped channels 614. In this example, the GAA transistor 600 includes an outer gate structure 618 and a plurality of inner gate structures 620. In an aspect, the outer gate structure 618 includes a gate contact 622 that is bounded at its exterior by a layer 624 of a work function metal. In turn, the layer 624 of the work function metal is bounded at its exterior by a gate dielectric layer 626, which is typically formed from a high dielectric constant material.

In the example shown in FIG. 6A, the outer gate structure 618 is associated with a corresponding outer gate spacer 628. Unlike conventional outer gate spacers, outer gate spacer 628 is formed as a multi-layer dielectric structure. In an aspect, the outer gate spacer 628 includes an interior wall 634 disposed next to the outer gate structure 618 (shown in this example as immediately adjacent to the gate dielectric layer 626). In an aspect, the interior wall 634 is formed from a high dielectric constant material. The outer gate spacer 628 also includes an exterior wall 636 that is laterally spaced from the interior wall 634 and also formed from a high dielectric constant material, which may be the same or a different dielectric material than used for the interior wall 634. Still further, the outer gate spacer 628 includes a low dielectric constant material 638 disposed between the interior wall 634 and the exterior wall 636. In accordance with certain aspects of the disclosure, the outer gate spacer 628 also includes an upper wall 670 formed from a high dielectric constant material that overlies the low dielectric constant material 638 and extends between the interior wall 634 and the exterior wall 636. Additionally, the outer gate spacer 628 includes a lower wall 672 of a high dielectric constant material below the low dielectric constant material 638 that extends between the interior wall 634 and the exterior wall 636. In an aspect, the interior wall 634, the exterior wall 636, the upper wall 670, and the lower wall 672 may be formed from the same or different high dielectric constant materials. In an aspect, the walls 634, 636, 670, and 672 may be formed from a high dielectric constant material such as SiN. The low dielectric constant material 638 may be a low dielectric constant material such as SiO2, an air gap, or any combination thereof. In an aspect, the low dielectric constant material 638 is formed as a single layer that extends from an interior surface of the interior wall 634 and an interior surface of the exterior wall 636. The GAA transistor 600 may also include, dummy gate spacers (not shown) that have a similar multi-layer dielectric structure as the outer gate spacer 628.

In an aspect, each inner gate structure 620 includes an interior layer of a work function metal 630 that is surrounded by a gate dielectric layer 632. Each inner gate structure 620 is associated with a corresponding inner gate spacer 640. Unlike conventional inner gate spacers, inner gate spacers 640 are formed as multi-layer dielectric structures. In an aspect, each inner gate spacer 640 includes an interior wall 642 disposed next to the corresponding inner gate structure 620 (shown in this example as immediately adjacent to the gate dielectric layer 632). In an aspect, the interior wall 642 is formed from a fifth high dielectric constant material. Each inner gate spacer 640 also includes an exterior wall 644 that is laterally spaced from the interior wall 642 and also formed from a high dielectric constant material, which may be the same or a different dielectric material than used for the interior wall 642. Still further, each inner gate spacer 640 includes a low dielectric constant material 646 disposed between the interior wall 642 and the exterior wall 644. In accordance with certain aspects of the disclosure, each inner gate spacer 640 also includes an upper wall 674 of a high dielectric constant material that overlies the low dielectric constant material 646 that extends between the interior wall 642 and the exterior wall 644. Additionally, each inner gate spacer 640 includes a lower wall 676 of a high dielectric constant material below the low dielectric constant material 646 that extends between the interior wall 642 and the exterior wall 636. In an aspect, the interior wall 642, the exterior wall 644, the upper wall 674, and the lower wall 676 may be formed from the same or different high dielectric constant materials. In an aspect, the walls 642, 644, 674, and 676 may be formed from a high dielectric constant material such as SiN. The low dielectric constant material 646 may be a low dielectric constant material such as SiO2, an air gap, or any combination thereof. In an aspect, the low dielectric constant material 646 is formed as a single layer that extends from an interior surface of the interior wall 642 and an interior surface of the exterior wall 644.

The foregoing elements of the GAA transistor 600 overlie a base structure 660. In this example, the base structure 660 includes a layer 662 that includes a doped well 664 and an STI structure 666. Layer 662 overlies a substrate layer 668. It will be recognized that the base structure 660 will be different depending on the starting elements used in the fabrication process (e.g., bulk, SOI, etc.).

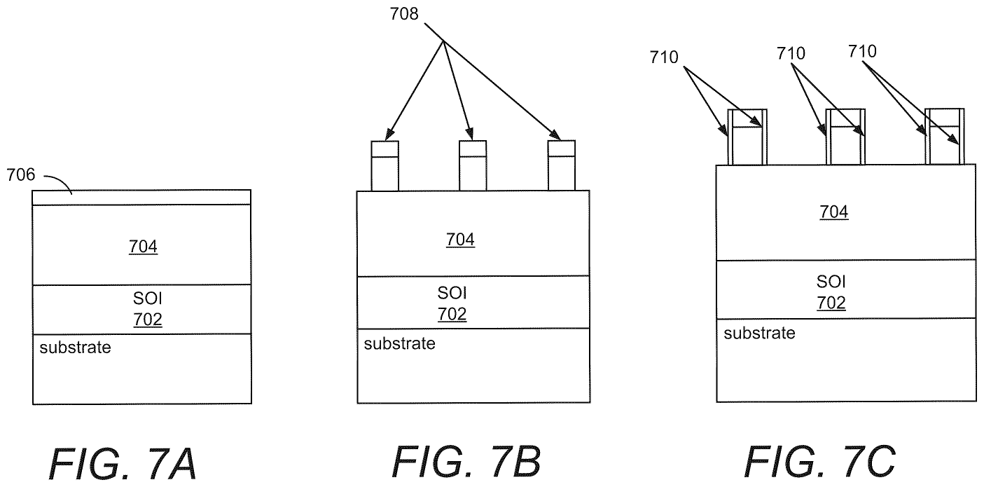

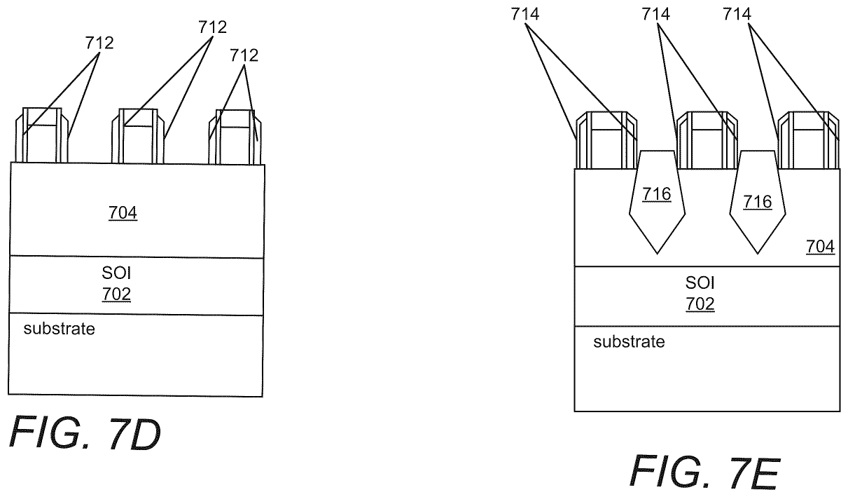

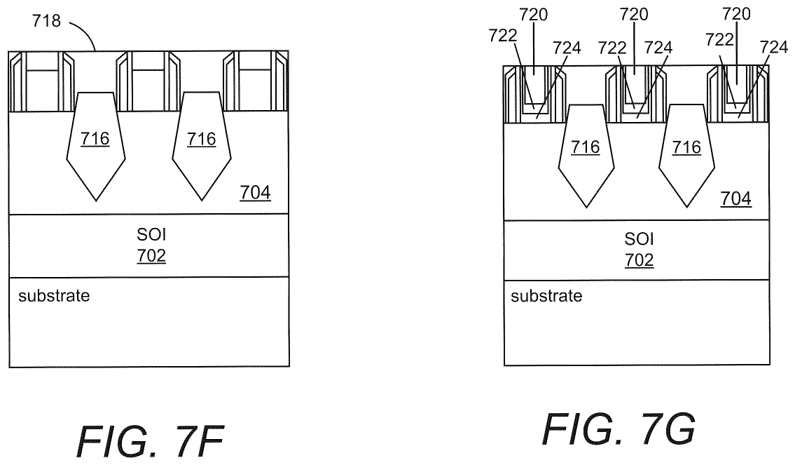

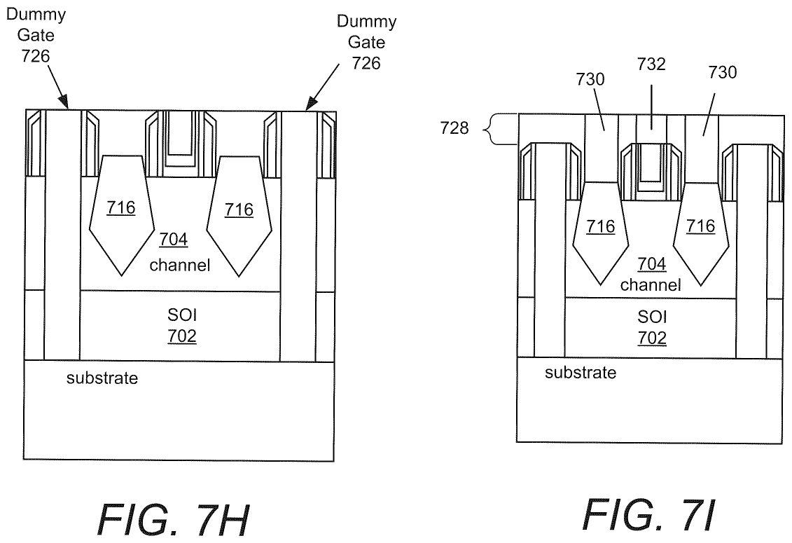

FIG. 7A through FIG. 7I show an example process that may be used to fabricate a FinFET, according to aspects of the disclosure. In this example process, fabrication starts at FIG. 7A with an SOI substrate 702 on which P and N for the device are formed doped layer 704. After patterning, a high dielectric constant layer (e.g., SiN) 706 is deposited. The resulting structure is then patterned to form the fin followed by the deposition of an STI oxide that is subject to a chemical mechanical polishing (CMP) operation. The oxide is then recessed to form the STI structures and the high dielectric constant layer is removed.

In FIG. 7B, a dummy polysilicon layer and hard mask layer are deposited and then patterned to form the gate elements 708 that are ultimately used to form the gate structure (the center gate element) and dummy gates (the outer gate elements).

In FIG. 7C, a thin SiN layer (e.g., 1˜2 nm) is deposited and then etched back to form the interior wall 710 of what will ultimately become the gate spacers.

In FIG. 7D, a thin layer of low dielectric constant material (e.g., 2˜5 nm of SiO2) is deposited. The layer is then etched back and recessed to form what will ultimately become the low dielectric constant layer 712 of the gate spacers.

In FIG. 7E, a thin layer of high dielectric constant material (e.g., 1˜3 nm of SiN) is deposited and then etched back to form what will ultimately become the outer wall 714 of the gate spacer. At this point, the gate spacers (both the actual gate spacers and the dummy gate spacers) have been formed as multi-layer dielectric gate spacers. The source and drain regions of the fin are recessed and the epitaxial structures 716 (e.g., the S/D structures) are formed (e.g., eSiGe for a P-channel metal oxide semiconductor device or eSi for an n-channel metal oxide semiconductor device). If an air gap is used as the low dielectric constant material, the material deposited for the middle layer in the process step shown in FIG. 7D may be a sacrificial layer (e.g., air gap film) that is removed (e.g., using a thermal process).

In FIG. 7F, an inter-layer dielectric oxide 718 is deposited and subject to a CMP process.

In FIG. 7G, the dummy polysilicon gate area is removed. The area left as a result of the removal of the dummy polysilicon gate area is filled with the metal gate contact 720, the work function metal 722, and the gate dielectric 724 to form the gate structure of the FinFET.

In FIG. 7H, the material is removed from the dummy gates 726.

In FIG. 7I, the FinFET fabrication is completed. To this end, another interlayer dielectric 728 is deposited and patterned to open areas for the deposition of the metallization structures 730 used to contact the epitaxial structures 716. Likewise, the interlayer dielectric 728 is patterned to open areas for the metal structure 732 that is used to provide an electrical path to the gate contact of the gate structure. A CMP process may be performed after the deposition of each metallization layer forming the metal structures.

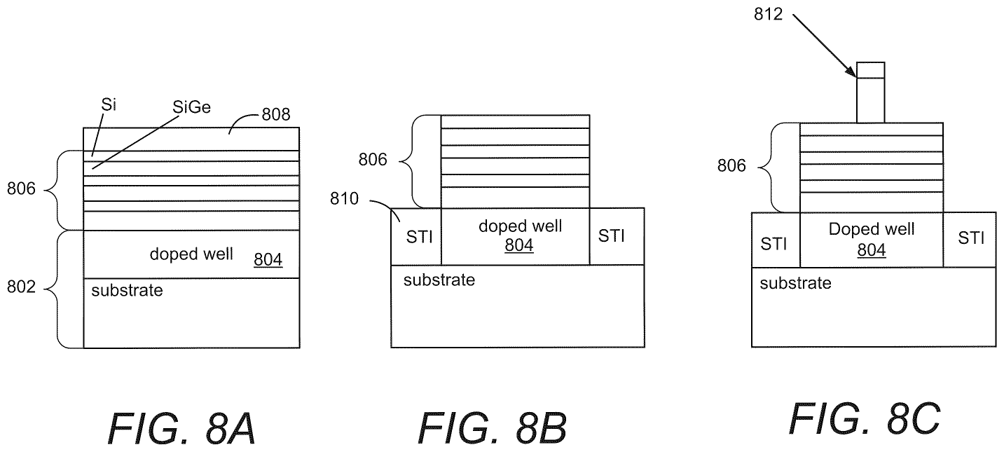

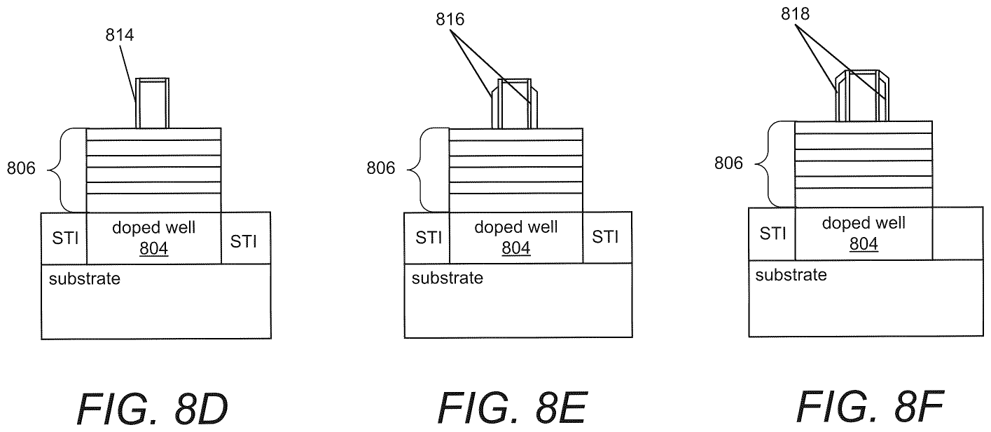

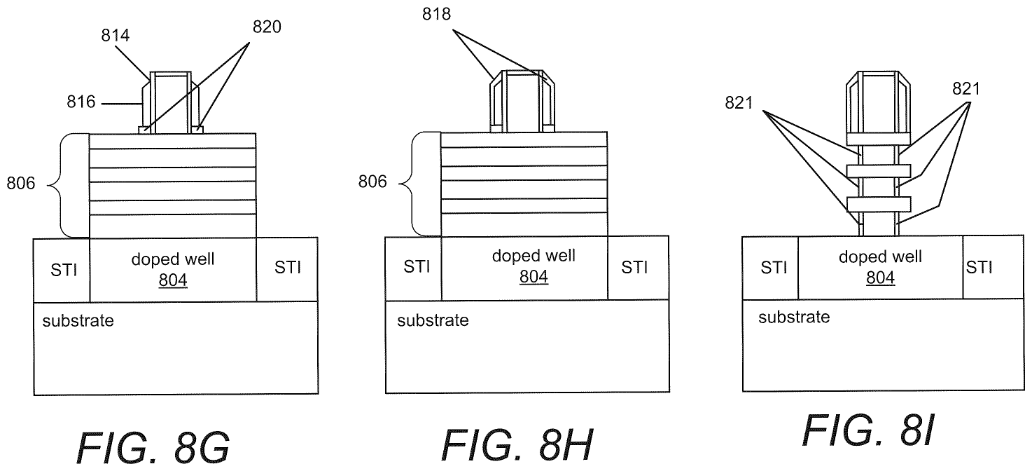

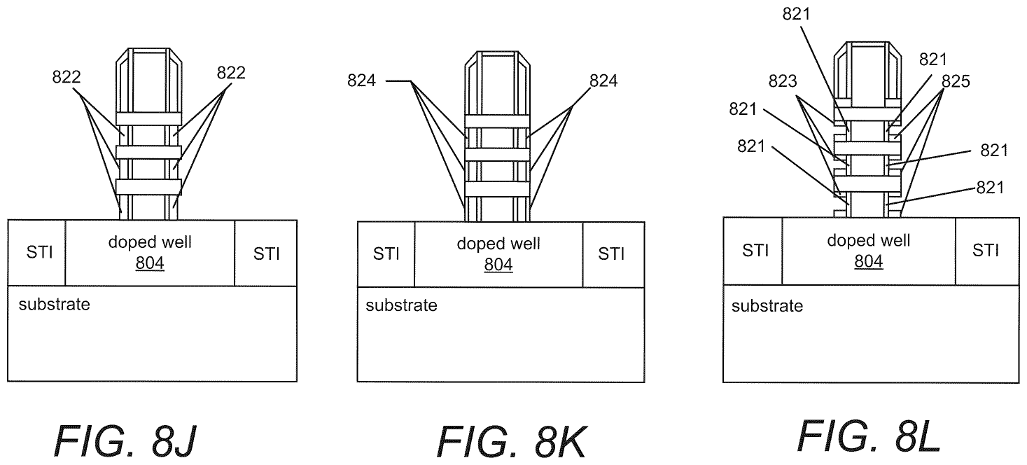

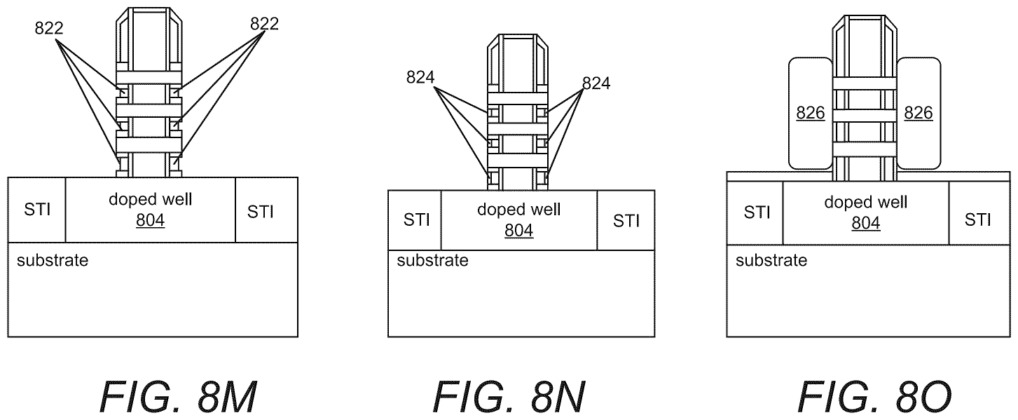

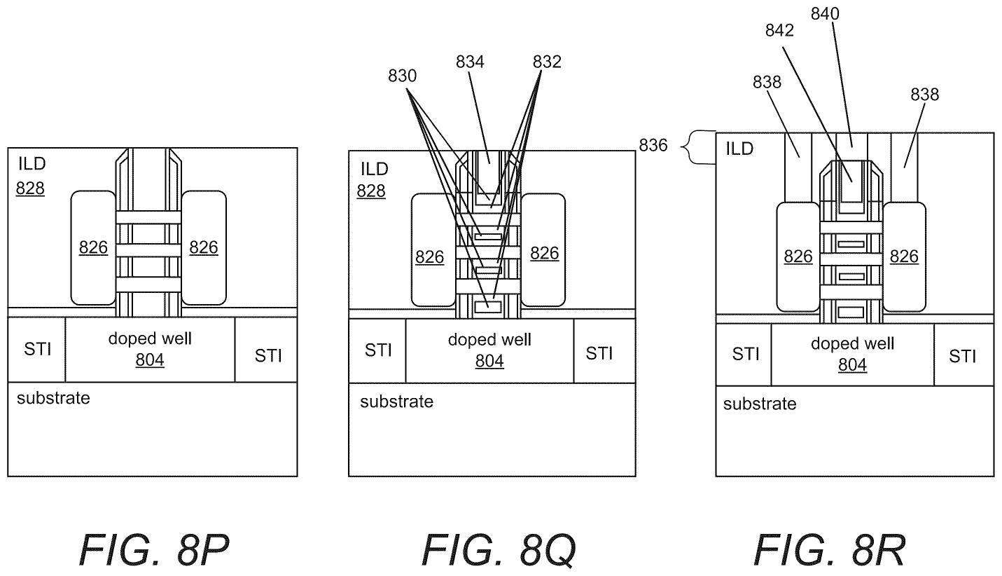

FIG. 8A through FIG. 8R show an example process that may be used to fabricate a GAA transistor, according to aspects of the disclosure. In this example process, fabrication starts at FIG. 8A with a substrate base 802 in which a doped well 804 is implanted. A multi-layer structure 806 comprised of alternating layers of epitaxial materials (e.g., SiGe/Si layers, each having a thickness of 8˜10 nm) are deposited over the doped well 804. A layer of a high dielectric constant material 808 (e.g., SiN) is deposited over the top epitaxial layer.

In FIG. 8B, the active regions of the device are patterned in the doped well 804. A layer of STI oxide is deposited, followed by a CMP process. The STI oxide is recessed to form STI structures 810 and the hard mask (not shown) used in the patterning process is removed.

In FIG. 8C, a polysilicon layer and patterned hard mask are deposited and etched to form a gate element 812.

In FIG. 8D, a thin layer of high dielectric constant material (e.g., 1˜2 nm of SiN) is deposited over the polysilicon layer and etched back to the proper thickness to form what will ultimately become the interior wall 814 of the outer gate spacer.

In FIG. 8E, a thin layer of low dielectric constant material (e.g., 2˜3 nm of oxide) is deposited and etched back to form what will ultimately become the low dielectric constant material 816 of the outer gate spacer.

In FIG. 8F, a thin layer of high dielectric constant material (e.g., 1˜2 nm of SiN) is deposited and etched back to form what will ultimately become the exterior wall 818 of the outer gate spacer.

Optional processing of the outer gate spacer is shown in FIGS. 8G and 8H. As shown in FIGS. 8G and 8H, optional lower walls 820 of high dielectric constant material may be deposited and etched back prior to the operations used to form the interior wall 814, exterior wall 818, and low dielectric constant material 816 of the outer gate spacer.

In FIG. 81, the formation of the inner gate structures, inner gate spacers, and doped channels begin. During the initial inner structure processing, the nanosheets are cut to the same width as the outer gate spacer. Further, etching operations are used to form the recesses in the SiGe dummy nanosheets in which the inner gate spacers are to be formed.

A thin layer of high dielectric constant material (e.g., ˜1˜2 nm SiN) is deposited and etched back to form what will ultimately become the interior walls 821 of the inner gate spacers.

In FIG. 8J, a thin layer of low dielectric constant material (e.g., 1˜2 nm oxide layer) is deposited and etched back to form what will ultimately become the low dielectric constant material 822 of the inner gate spacers.

In FIG. 8K, a thin layer of high dielectric constant material (e.g., 1˜2 nm of SiN) is deposited and etched back to form what will ultimately become the exterior walls 824 of the inner gate spacers. If the low dielectric constant material is to be an airgap, a dummy airgap film may be deposited instead of the low dielectric constant material. The dummy airgap film may be subsequently removed using, for example, a thermal process, to leave behind airgaps as the middle low dielectric constant layers of the inner gate spacers.

In an aspect, the dielectric material used to form the inner walls may be deposited to fill the recesses of the inner bate spacers and etched back to leave not only the inner wall 821, but also optional upper and lower walls 823 and 825 of high dielectric constant material as shown in FIGS. 8L through 8M. In an aspect, the inner wall 821, optional upper walls 823, and optional lower walls 825 may be formed from SiN and have a thickness of 1˜2 nm. After formation of the inner walls 821, and the upper walls 823, and lower walls 825 of the inner gate spacers, the low dielectric constant material 822 of the inner gate spacers may be deposited and etched back (FIG. 8M) followed by deposition and etch back of the high dielectric constant material (FIG. 8N) ultimately used to form the exterior walls 824 of the inner gate spacers.

In FIG. 8O, a thin oxide layer (option) is deposited and etched to expose the nanosheets that form the doped channels. Epitaxial structures 826 forming the S/D structures are fabricated (e.g., using eSiGe for fabricating a PMOS device or eSi for fabricating and NMOS device).

In FIG. 8P, an interlayer dielectric ILD oxide film 828 is deposited and subject to a CMP process. Additionally, the sacrificial polysilicon material and dummy SiGe layers are removed to open the regions that will be used to form the inner and outer gate structures.

In FIG. 8Q, the area left as a result of the removal of the sacrificial polysilicon material is filled with the work function metal 830 and the gate dielectric 832 to form the gate structures. Additionally, the metallization 834 for the gate contact may be deposited and subject to a CMP process.

In FIG. 8R, the fabrication of the GAA transistor is completed. To this end, a further layer of interlayer dielectric 836 is deposited to build up the interlayer dielectric so that it extends above the outer gate structure. The interlayer dielectric is then patterned to open areas for the deposition of the metallization structures 838 used to contact the epitaxial structures 826. Likewise, the interlayer dielectric is patterned to open areas for the metal structure 840 that is used to provide an electrical path to the gate contact 842 of the outer gate structure. A CMP process may be performed after the deposition of each metallization layer forming the metal structures.

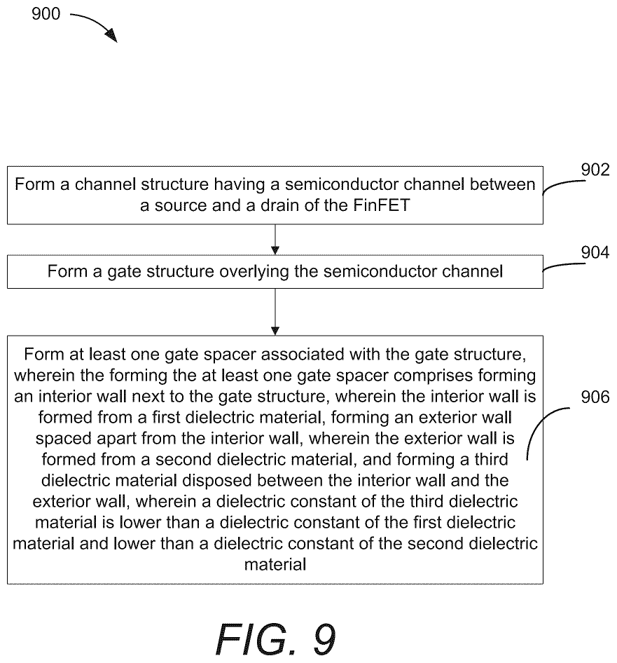

FIG. 9 is a flowchart showing an example method 900 for fabricating a FinFET, according to aspects of the disclosure. At operation 902, a channel structure is formed that has a semiconductor channel separating a source and drain of the FinFET. At operation 904, a gate structure overlying the semiconductor channel is formed. At operation 906, at least one gate spacer associated with the gate structure is formed, wherein the forming the at least one gate spacer comprises forming an interior wall next to the gate structure, wherein the interior wall is formed from a first dielectric material, forming an exterior wall spaced apart from the interior wall, wherein the exterior wall is formed from a second dielectric material, and forming a third dielectric material disposed between the interior wall and the exterior wall, wherein a dielectric constant of the third dielectric material is lower than a dielectric constant of the first dielectric material and lower than a dielectric constant of the second dielectric material.

A technical advantage of the method 900 is that it forms a FinFET having reduced parasitic capacitances. By reducing the parasitic capacitances, the FinFET consumes less power and can operate at higher speeds.

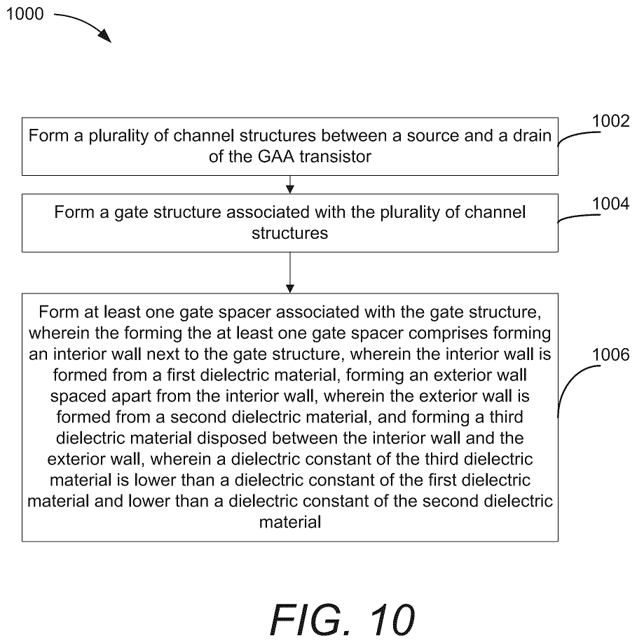

FIG. 10 is a flowchart showing an example method 1000 for fabricating a GAA transistor, according to aspects of the disclosure. At operation 1002, a plurality of channel structures are formed between a source and a drain of the GAA transistor. At operation 1004, a gate structure associated with the plurality of channel structures is formed. At operation 1006, at least one gate spacer associated with the gate structure is formed, wherein the forming the at least one gate spacer comprises forming an interior wall next to the gate structure, wherein the interior wall is formed from a first dielectric material, forming an exterior wall spaced apart from the interior wall, wherein the exterior wall is formed from a second dielectric material, and forming a third dielectric material disposed between the interior wall and the exterior wall, wherein a dielectric constant of the third dielectric material is lower than a dielectric constant of the first dielectric material and lower than a dielectric constant of the second dielectric material.

A technical advantage of the method 1000 is that it forms a GAA transistor having reduced parasitic capacitances. By reducing the parasitic capacitances, the GAA transistor consumes less power and can operate at higher speeds.

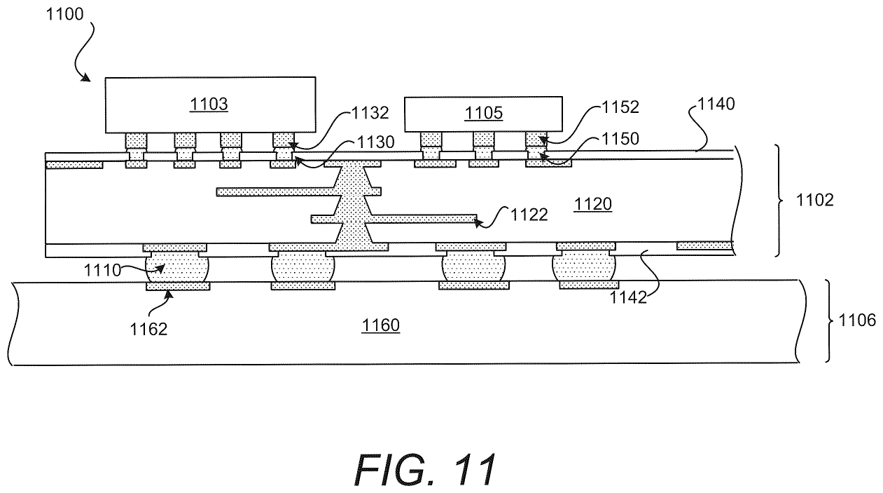

FIG. 11 illustrates a profile view of a package 1100 that includes a surface mount substrate 1102, an integrated device 1103, and an integrated passive device 1105, according to aspects of the disclosure. The package 1100 may be coupled to a printed circuit board (PCB) 1106 through a plurality of solder interconnects 1110. The PCB 1106 may include at least one board dielectric layer 1160 and a plurality of board interconnects 1162.

The surface mount substrate 1102 includes at least one dielectric layer 1120 (e.g., substrate dielectric layer), a plurality of interconnects 1122 (e.g., substrate interconnects), a solder resist layer 1140 and a solder resist layer 1142. The integrated device 1103 may be coupled to the surface mount substrate 1102 through a plurality of solder interconnects 1130. The integrated device 1103 may be coupled to the surface mount substrate 1102 through a plurality of pillar interconnects 1132 and the plurality of solder interconnects 1130. The integrated passive device 1105 may be coupled to the surface mount substrate 1102 through a plurality of solder interconnects 1150. The integrated passive device 1105 may be coupled to the surface mount substrate 1102 through a plurality of pillar interconnects 1152 and the plurality of solder interconnects 1150.

The package (e.g., 1100) may be implemented in a radio frequency (RF) package. The RF package may be a radio frequency front end (RFFE) package. A package (e.g., 1100) may be configured to provide Wireless Fidelity (WiFi) communication and/or cellular communication (e.g., 2G, 3G, 4G, 5G). The package (e.g., 1100) may be configured to support Global System for Mobile (GSM) Communications, Universal Mobile Telecommunications System (UMTS), and/or Long-Term Evolution (LTE). The package (e.g., 1100) may be configured to transmit and receive signals having different frequencies and/or communication protocols.

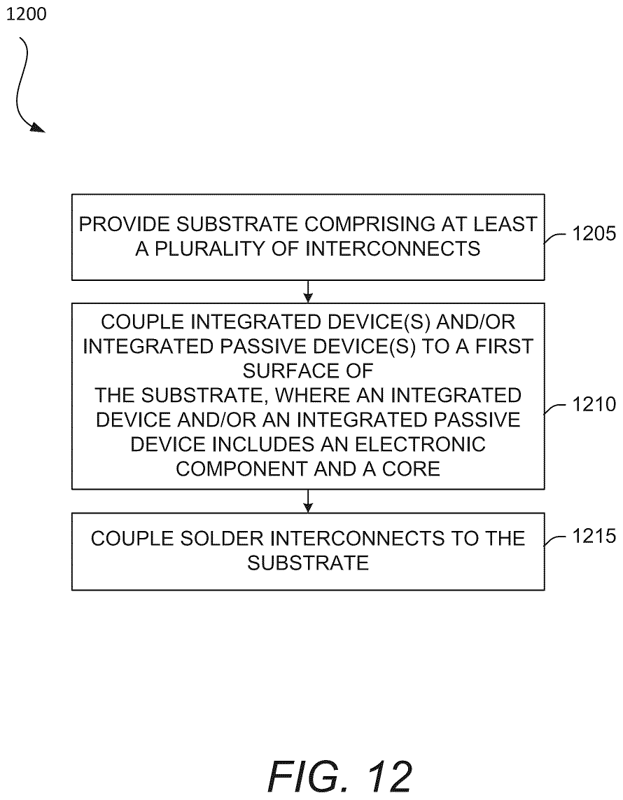

FIG. 12 illustrates an example method 1200 for providing or fabricating a package that includes an integrated device comprising an electronic component mounted in a core, according to aspects of the disclosure. In some implementations, the method 1200 of FIG. 12 may be used to provide or fabricate the package 1100 of FIG. 11 described in the disclosure. However, the method 1200 may be used to provide or fabricate any of the packages described in the disclosure.

It should be noted that the method of FIG. 12 may combine one or more processes in order to simplify and/or clarify the method for providing or fabricating a package that includes an integrated device comprising an electronic component mounted in a core, according to aspects of the disclosure. In some implementations, the order of the processes may be changed or modified.

The method provides (at 1205) a substrate (e.g., 1102). The substrate 1102 may be provided by a supplier or fabricated. The substrate 1102 includes at least one dielectric layer 1120, and a plurality of interconnects 1122. The substrate 1102 may include an embedded trace substrate (ETS). In some implementations, the at least one dielectric layer 1120 may include prepreg layers.

The method couples (at 1210) at least one integrated device (e.g., 1103) to the first surface of the substrate (e.g., 1102). For example, the integrated device 1103 may be coupled to the substrate 1102 through the plurality of pillar interconnects 1132 and the plurality of solder interconnects 1130. The plurality of pillar interconnects 1132 may be optional.

The plurality of solder interconnects 1130 are coupled to the plurality of interconnects 1122. A solder reflow process may be used to couple the integrated device 1103 to the plurality of interconnects through the plurality of solder interconnects 1130.

The method also couples (at 1210) at least one integrated passive device (e.g., 1105) to the first surface of the substrate (e.g., 1102). For example, the integrated passive device 1105 may be coupled to the substrate 1102 through the plurality of pillar interconnects 1152 and the plurality of solder interconnects 1150. The plurality of pillar interconnects 1152 may be optional. The plurality of solder interconnects 1150 are coupled to the plurality of interconnects 1122. A solder reflow process may be used to couple the integrated passive device 1105 to the plurality of interconnects through the plurality of solder interconnects 1150.

The method couples (at 1215) a plurality of solder interconnects (e.g., 1110) to the second surface of the substrate (e.g., 1102). A solder reflow process may be used to couple the plurality of solder interconnects 1110 to the substrate.

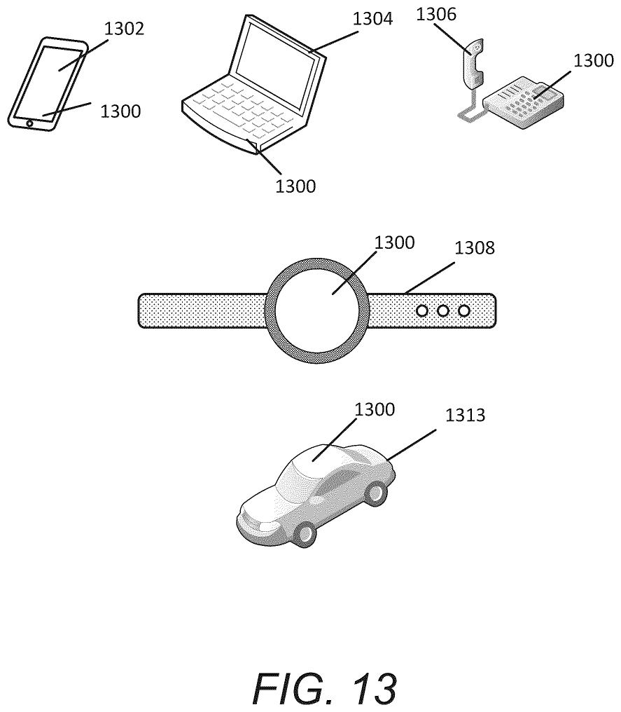

FIG. 13 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1302, a laptop computer device 1304, a fixed location terminal device 1306, a wearable device 1308, or automotive vehicle 1313 may include a device 1300 as described herein. The device 1300 may be, for example, any of the devices and/or integrated circuit (IC) packages described herein. The devices 1302, 1304, 1306 and 1308 and the vehicle 1313 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device having one or more non-planar transistors, at least one of the one or more non-planar transistors comprising: one or more gate structures; and one or more gate spacers respectively associated with each of the one or more gate structures, at least one gate spacer of the one or more gate spacers having a multi-layer dielectric structure comprising an interior wall disposed next to a respective gate structure of the one or more gate structures, wherein the interior wall is formed from a first dielectric material, an exterior wall spaced apart from the interior wall, wherein the exterior wall is formed from a second dielectric material, and a third dielectric material disposed between the interior wall and the exterior wall, wherein a dielectric constant of the third dielectric material is lower than a dielectric constant of the first dielectric material and lower than a dielectric constant of the second dielectric material.

Aspect 2. The electronic device of aspect 1, wherein: the interior wall is disposed adjacent a gate dielectric layer of the respective gate structure.

Aspect 3. The electronic device of any of aspects 1 to 2, wherein: the first dielectric material and the second dielectric material are a same dielectric material.

Aspect 4. The electronic device of any of aspects 1 to 3, wherein: the third dielectric material comprises an air gap.

Aspect 5. The electronic device of any of aspects 1 to 4, wherein the one or more gate spacers further comprise: an upper wall of a fourth dielectric material overlying the third dielectric material and extending between the interior wall and the exterior wall; and a lower wall of a fifth dielectric material below the third dielectric material and extending between the interior wall and the exterior wall.

Aspect 6. The electronic device of aspect 5, wherein: the first dielectric material, the second dielectric material, the fourth dielectric material, and the fifth dielectric material are a same dielectric material.

Aspect 7. The electronic device of any of aspects 1 to 6, wherein: the third dielectric material extends from an interior surface of the interior wall and an interior surface of the exterior wall.

Aspect 8. The electronic device of any of aspects 1 to 7, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.

Aspect 9. A non-planar transistor comprising: one or more gate structures; and one or more gate spacers respectively associated with each of the one or more gate structures, at least one gate spacer of the one or more gate spacers having a multi-layer dielectric structure comprising an interior wall disposed next to a respective gate structure of the one or more gate structures, wherein the interior wall is formed from a first dielectric material, an exterior wall spaced apart from the interior wall, wherein the exterior wall is formed from a second dielectric material, and a third dielectric material disposed between the interior wall and the exterior wall, wherein a dielectric constant of the third dielectric material is lower than a dielectric constant of the first dielectric material and lower than a dielectric constant of the second dielectric material.

Aspect 10. The non-planar transistor of aspect 9, wherein: the interior wall is disposed adjacent a gate dielectric layer of the respective gate structure.

Aspect 11. The non-planar transistor of any of aspects 9 to 10, wherein: the first dielectric material and the second dielectric material are a same dielectric material.

Aspect 12. The non-planar transistor of any of aspects 9 to 11, wherein: the third dielectric material comprises an air gap.

Aspect 13. The non-planar transistor of any of aspects 9 to 12, wherein the one or more gate spacers further comprise: an upper wall of a fourth dielectric material overlying the third dielectric material and extending between the interior wall and the exterior wall; and a lower wall of a fifth dielectric material below the third dielectric material and extending between the interior wall and the exterior wall.

Aspect 14. The non-planar transistor of aspect 13, wherein: the first dielectric material, the second dielectric material, the fourth dielectric material, and the fifth dielectric material are a same dielectric material.

Aspect 15. The non-planar transistor of any of aspects 9 to 14, wherein: the third dielectric material extends from an interior surface of the interior wall and an interior surface of the exterior wall.

Aspect 16. A method of forming a fin field effect transistor (FinFET), comprising: forming a channel structure having a semiconductor channel between a source and a drain of the FinFET; forming a gate structure overlying the semiconductor channel; and forming at least one gate spacer associated with the gate structure, wherein the forming the at least one gate spacer comprises forming an interior wall next to the gate structure, wherein the interior wall is formed from a first dielectric material, forming an exterior wall spaced apart from the interior wall, wherein the exterior wall is formed from a second dielectric material, and forming a third dielectric material disposed between the interior wall and the exterior wall, wherein a dielectric constant of the third dielectric material is lower than a dielectric constant of the first dielectric material and lower than a dielectric constant of the second dielectric material.

Aspect 17. A method of forming a gate-all-around (GAA) transistor, comprising: forming a plurality of channel structures between a source and a drain of the GAA transistor; forming a gate structure associated with the plurality of channel structures; and forming at least one gate spacer associated with the gate structure, wherein the forming the at least one gate spacer comprises forming an interior wall next to the gate structure, wherein the interior wall is formed from a first dielectric material, forming an exterior wall spaced apart from the interior wall, wherein the exterior wall is formed from a second dielectric material, and forming a third dielectric material disposed between the interior wall and the exterior wall, wherein a dielectric constant of the third dielectric material is lower than a dielectric constant of the first dielectric material and lower than a dielectric constant of the second dielectric material.

Aspect 18. The method of aspect 17, wherein: the first dielectric material and the second dielectric material are a same dielectric material.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component).

Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect (s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device having one or more non-planar transistors, at least one of the one or more non-planar transistors comprising:
one or more gate structures; and
one or more gate spacers respectively associated with each of the one or more gate structures, at least one gate spacer of the one or more gate spacers having a multi-layer dielectric structure comprising
an interior wall disposed next to a respective gate structure of the one or more gate structures, wherein the interior wall is formed from a first dielectric material,
an exterior wall spaced apart from the interior wall, wherein the exterior wall is formed from a second dielectric material, and
a third dielectric material disposed between the interior wall and the exterior wall, wherein a dielectric constant of the third dielectric material is lower than a dielectric constant of the first dielectric material and lower than a dielectric constant of the second dielectric material.

2. The electronic device of claim 1, wherein:
the interior wall is disposed adjacent a gate dielectric layer of the respective gate structure.

3. The electronic device of claim 1, wherein:
the first dielectric material and the second dielectric material are a same dielectric material.

4. The electronic device of claim 1, wherein:
the third dielectric material comprises an air gap.

5. The electronic device of claim 1, wherein the one or more gate spacers further comprise:
an upper wall of a fourth dielectric material overlying the third dielectric material and extending between the interior wall and the exterior wall; and
a lower wall of a fifth dielectric material below the third dielectric material and extending between the interior wall and the exterior wall.

6. The electronic device of claim 5, wherein:
the first dielectric material, the second dielectric material, the fourth dielectric material, and the fifth dielectric material are a same dielectric material.

7. The electronic device of claim 1, wherein:
the third dielectric material extends from an interior surface of the interior wall and an interior surface of the exterior wall.

8. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

9. A non-planar transistor comprising:
one or more gate structures; and
one or more gate spacers respectively associated with each of the one or more gate structures, at least one gate spacer of the one or more gate spacers having a multi-layer dielectric structure comprising
an interior wall disposed next to a respective gate structure of the one or more gate structures, wherein the interior wall is formed from a first dielectric material,
an exterior wall spaced apart from the interior wall, wherein the exterior wall is formed from a second dielectric material, and
a third dielectric material disposed between the interior wall and the exterior wall, wherein a dielectric constant of the third dielectric material is lower than a dielectric constant of the first dielectric material and lower than a dielectric constant of the second dielectric material.

10. The non-planar transistor of claim 9, wherein:
the interior wall is disposed adjacent a gate dielectric layer of the respective gate structure.

11. The non-planar transistor of claim 9, wherein:
the first dielectric material and the second dielectric material are a same dielectric material.

12. The non-planar transistor of claim 9, wherein:
the third dielectric material comprises an air gap.

13. The non-planar transistor of claim 9, wherein the one or more gate spacers further comprise:
an upper wall of a fourth dielectric material overlying the third dielectric material and extending between the interior wall and the exterior wall; and
a lower wall of a fifth dielectric material below the third dielectric material and extending between the interior wall and the exterior wall.

14. The non-planar transistor of claim 13, wherein:
the first dielectric material, the second dielectric material, the fourth dielectric material, and the fifth dielectric material are a same dielectric material.

15. The non-planar transistor of claim 9, wherein:
the third dielectric material extends from an interior surface of the interior wall and an interior surface of the exterior wall.

16. A method of forming a fin field effect transistor (FinFET), comprising:
forming a channel structure having a semiconductor channel between a source and a drain of the FinFET;
forming a gate structure overlying the semiconductor channel; and
forming at least one gate spacer associated with the gate structure, wherein the forming the at least one gate spacer comprises
forming an interior wall next to the gate structure, wherein the interior wall is formed from a first dielectric material,
forming an exterior wall spaced apart from the interior wall, wherein the exterior wall is formed from a second dielectric material, and
forming a third dielectric material disposed between the interior wall and the exterior wall, wherein a dielectric constant of the third dielectric material is lower than a dielectric constant of the first dielectric material and lower than a dielectric constant of the second dielectric material.

17. A method of forming a gate-all-around (GAA) transistor, comprising:
forming a plurality of channel structures between a source and a drain of the GAA transistor;
forming a gate structure associated with the plurality of channel structures; and
forming at least one gate spacer associated with the gate structure, wherein the forming the at least one gate spacer comprises
forming an interior wall next to the gate structure, wherein the interior wall is formed from a first dielectric material,
forming an exterior wall spaced apart from the interior wall, wherein the exterior wall is formed from a second dielectric material, and
forming a third dielectric material disposed between the interior wall and the exterior wall, wherein a dielectric constant of the third dielectric material is lower than a dielectric constant of the first dielectric material and lower than a dielectric constant of the second dielectric material.

18. The method of claim 17, wherein:
the first dielectric material and the second dielectric material are a same dielectric material.
